(19) United States
(12) Patent Application Publication
(10) Pub. No.: US 2025/0316493 A1
(43) Pub. Date: Oct. 9, 2025

(54) SEMICONDUCTOR DEVICE AND METHOD FOR MANUFACTURING THE SAME

(71) Applicant: Hangzhou HFC Semiconductor Co., Hangzhou (CN)

(72) Inventors: Mao SUN, Hangzhou (CN); Lixiang GAO, Hangzhou (CN); John Hongguang ZHANG, Altamont, NY (US)

(73) Assignee: Hangzhou HFC Semiconductor Co., Hangzhou (CN)

(21) Appl. No.: 18/657,762

(22) Filed: May 7, 2024

(30) Foreign Application Priority Data
Apr. 9, 2024 (CN) 202410423676.5

(51) Int. Cl. H01L 21/311; H01L 21/3213; H01L 27/088

(52) U.S. Cl. CPC H01L 21/31144; H01L 21/32139; H10D 84/83

(57) ABSTRACT

This application provides a semiconductor device and a method for manufacturing the same. The method includes: providing a semiconductor substrate, on which gate structures and a first dielectric layer are formed; replacing a portion of the first dielectric layer away from the semiconductor substrate with a second dielectric layer; forming a patterned third dielectric layer on the gate structure and the second dielectric layer, wherein the third dielectric layer has an opening exposing a surface of a predetermined gate removal area of the gate structure; using the third dielectric layer as a mask to selectively remove the gate structure exposed by the opening to form a gate cutting groove; forming a fourth dielectric layer in the gate cutting groove; and removing the third dielectric layer and the fourth dielectric layer that are higher than the gate structure through a planarization process to form a partially cut gate structure.

### CROSS REFERENCE TO RELATED APPLICATION

This application claims the benefit of and priority from Chinese Patent Application No. 202410423676.5, filed on Apr. 9, 2024, the entire disclosure of which is incorporated herein by reference for all purposes.

### TECHNICAL FIELD

This application belongs to the field of semiconductor design and manufacturing, and particularly relates to semiconductor devices and methods for manufacturing the same.

### BACKGROUND

Metal-Oxide-Semiconductor (MOS) device is an important device widely used in integrated circuits and microelectronics technology and plays a key role in modern electronic equipment and chips.

During the preparation process of the gate structure of a metal oxide semiconductor, continuous linear gate structures extending across the entire semiconductor substrate are initially formed, and the spaces between the continuous linear gate structures are filled with flowable oxide (hereinafter referred to as FOX). In order to optimize device performance, reduce crosstalk effects between devices, and improve power tolerance, signal transmission efficiency, etc., the continuous linear gate structure needs to be cut to remove a portion of the continuous linear gate structure to form separated gate structures. These separated gate structures can be either the final gate structure of the metal oxide semiconductor device in the gate-fist manufacturing process, or the sacrificial gate structure in the gate-last manufacturing process.

When performing gate cutting, a patterned photoresist layer needs to be formed on the continuous linear gate structure and FOX. The patterned photoresist layer has an opening, which exposes a portion of the surface of the continuous linear gate structure. Next, the portion of the continuous linear gate structure exposed by the opening is removed through one or more etching processes to form a gate cutting groove that divides the continuous linear gate structure into separated gate structures. Next, the patterned photoresist layer is removed, the gate cutting groove is filled with FOX, and the portion of FOX higher than the separated gate structure is removed through a planarization process.

### SUMMARY

This application provides a semiconductor device and a method for manufacturing a semiconductor device.

According to an aspect of the present application, a method for manufacturing a semiconductor device includes: providing a semiconductor substrate, on which a plurality of gate structures arranged at intervals and a first dielectric layer filling a gap between adjacent gate structures are formed; replacing a portion of the first dielectric layer away from the semiconductor substrate with a second dielectric layer; forming a patterned third dielectric layer on the gate structure and the second dielectric layer, wherein the third dielectric layer has an opening, and the opening exposes a surface of a predetermined gate removal area of the gate structure; using the third dielectric layer as a mask to selectively remove the gate structure exposed by the opening to form a gate cutting groove; forming a fourth dielectric layer in the gate cutting groove, wherein the fourth dielectric layer also covers the third dielectric layer; and removing the third dielectric layer and a portion of the fourth dielectric layer that are higher than the gate structure through a planarization process to form a partially cut gate structure.

In some embodiments of the present application, replacing a portion of the first dielectric layer away from the semiconductor substrate with a second dielectric layer includes: etching the first dielectric layer to remove the portion of the first dielectric layer away from the semiconductor substrate to form a trench; forming a second dielectric material layer in the trench, wherein the second dielectric material layer fills the trench and covers the gate structures on both sides of the trench; and removing a portion of the second dielectric material layer higher than the gate structure through a planarization process to form the second dielectric layer.

In some embodiments of the present application, the first dielectric layer includes a flowable dielectric layer; each of the second dielectric layer, the third dielectric layer, and the fourth dielectric layer includes a high-density plasma dielectric layer.

In some embodiments of the present application, forming a patterned third dielectric layer on the gate structure and the second dielectric layer includes: forming a patterned sacrificial mask layer on the gate structure and the second dielectric layer, wherein the sacrificial mask layer covers the surface of the predetermined gate removal area of the gate structure and a surface of a portion of the second dielectric layer on both sides of the gate structure; forming the third dielectric layer on the gate structure and a portion of the second dielectric layer that are not covered by the sacrificial mask layer; and selectively removing the sacrificial mask layer to form the opening in the third dielectric layer.

In some embodiments of the present application, the sacrificial mask layer is a polysilicon layer.

In some embodiments of the present application, forming the third dielectric layer on the gate structure and a portion of the second dielectric layer that are not covered by the sacrificial mask layer includes: forming a third dielectric material layer, wherein the third dielectric material layer covers the sacrificial mask layer and a surface of the gate structure and a surface of the portion of the second dielectric layer that are exposed by the sacrificial mask layer; and removing a portion of the third dielectric material layer higher than the sacrificial mask layer through a planarization process to form the third dielectric layer.

In some embodiments of the present application, a sidewall structure is further formed on a sidewall of the gate structure, the gate structure includes a gate sacrificial layer and a gate mask layer formed on the gate sacrificial layer, and the opening exposes the surface of the predetermined gate removal area of the gate structure and a surface of the sidewall structure on both sides of the gate structure.

In some embodiments of the present application, using the third dielectric layer as a mask to selectively remove the gate structure exposed by the opening to form a gate cutting groove includes: using the third dielectric layer as a mask to selectively remove the gate mask layer exposed by the opening to expose the gate sacrificial layer; using the third dielectric layer as a mask to selectively remove a portion of the sidewall structure exposed by the opening to form a sidewall support structure; and using the third dielectric layer as a mask to selectively remove the gate sacrificial layer exposed by the opening to form the gate cutting groove.

In some embodiments of the present application, in the step of replacing a portion of the first dielectric layer away from the semiconductor substrate with a second dielectric layer, a bottom surface of the second dielectric layer is lower than a top surface of the gate sacrificial layer.

In some embodiments of the present application, in a step of using the third dielectric layer as a mask to selectively remove a portion of the sidewall structure exposed by the opening to form a sidewall supporting structure, a top surface of the sidewall support structure is higher than or flush with a bottom surface of the second dielectric layer.

In order to achieve the above objectives and other related objectives, this application also provides a semiconductor device.

According to another aspect of the present application, a semiconductor device includes: a semiconductor substrate; a plurality of gate structures arranged at intervals on the semiconductor substrate, wherein a gate cutting groove is formed in the gate structure and passes through the gate structure along a height direction, and the gate cutting groove divides a corresponding gate structure into independent separated gate structures along an extending direction of the gate structure; and an interlayer dielectric layer formed on the semiconductor substrate, wherein the interlayer dielectric layer includes a first interlayer dielectric layer and a second interlayer dielectric layer that are arranged in a stacked way, the first interlayer dielectric layer fills a bottom of a gap between the gate structures, the second interlayer dielectric layer fills a top of the gap between the gate structures, and the second interlayer dielectric layer also fills the gate cutting groove.

In some embodiments of the present application, a sidewall support structure is provided between the first interlayer dielectric layer and a portion of the second interlayer dielectric layer filling the gate cutting groove.

The present application provides a semiconductor substrate on which a plurality of gate structures formed at intervals and a first dielectric layer filling between the gate structures are provided. A portion of the first dielectric layer away from the semiconductor substrate is replaced with a second dielectric layer. A patterned third dielectric layer is formed on the gate structure and the second dielectric layer, wherein the third dielectric layer has an opening, and the opening exposes a surface of a predetermined gate removal area of the gate structure. The third dielectric layer is used as a mask to selectively remove the gate structure exposed by the opening to form a gate cutting groove. A fourth dielectric layer is formed in the gate cutting groove, wherein the fourth dielectric layer also covers the third dielectric layer. The third dielectric layer and a portion of the fourth dielectric layer that are higher than the gate structure are removed through a planarization process to form a partially cut gate structure.

### BRIEF DESCRIPTION OF DRAWINGS

FIG. 1 shows a schematic flowchart of a method for manufacturing a semiconductor device according to exemplary embodiments of the present application.

FIG. 2a shows a schematic cross-sectional view of a device according to exemplary embodiments of the present application, in which gate structures are formed on a semiconductor substrate and a first dielectric layer is filled between the gate structures.

FIG. 2b shows a schematic top view of a device according to exemplary embodiments of the present application, in which gate structures are formed on a semiconductor substrate and a first dielectric layer is filled between the gate structures.

FIG. 3 shows a schematic cross-sectional view of a device according to exemplary embodiments of the present application, in which a first dielectric layer is etched to remove a portion of the first dielectric layer away from a semiconductor substrate to form a trench.

FIG. 4 shows a schematic cross-sectional view of a device according to exemplary embodiments of the present application, in which a second dielectric layer is formed in a trench.

FIG. 5a shows a schematic cross-sectional view of a device according to exemplary embodiments of the present application, in which a patterned sacrificial mask layer is formed on a gate structure and a second dielectric layer, and the patterned sacrificial mask layer covers the surface of a predetermined gate removal area of the gate structure.

FIG. 5b shows a schematic top view of a device according to exemplary embodiments of the present application, in which a patterned sacrificial mask layer is formed on a gate structure and a second dielectric layer, and the patterned sacrificial mask layer covers the surface of a predetermined gate removal area of the gate structure.

FIG. 6 shows a schematic cross-sectional view of a device according to exemplary embodiments of the present application, in which a third dielectric layer is formed on a gate structure and a second dielectric layer that are not covered by a patterned sacrificial mask layer.

FIG. 7 shows a schematic cross-sectional view of a device according to exemplary embodiments of the present application, in which a patterned sacrificial mask layer is selectively removed to form an opening in a third dielectric layer.

FIG. 8a shows a schematic cross-sectional view of a device according to exemplary embodiments of the present application, in which a gate mask layer exposed by an opening is selectively removed using a patterned third dielectric layer as a mask to reveal a gate sacrificial layer.

FIG. 8b shows a schematic top view of a device according to exemplary embodiments of the present application, in which a gate mask layer exposed by openings is selectively removed using a patterned third dielectric layer as a mask to reveal a gate sacrificial layer.

FIG. 9a shows a schematic cross-sectional view of a device according to exemplary embodiments of the present application, in which a gate sacrificial layer exposed by openings is selectively removed using a third dielectric layer as a mask to form a gate cutting groove.

FIG. 9b shows a schematic top view of a device according to exemplary embodiments of the present application, in which a gate sacrificial layer exposed by openings is selectively removed using a third dielectric layer as a mask to form gate cutting grooves.

FIG. 10 shows a schematic cross-sectional view of a device according to exemplary embodiments of the present application, in which a fourth dielectric layer is formed, and the fourth dielectric layer fills gate cutting grooves and both sides of a gate cutting groove on a third dielectric layer.

FIG. 11a shows a schematic cross-sectional view of a device according to exemplary embodiments of the present application, in which a third dielectric layer and a fourth dielectric layer that are higher than gate structures are removed through a planarization process.

FIG. 11b shows a schematic top view of a device according to exemplary embodiments of the present application, in which a third dielectric layer and a fourth dielectric layer that are higher than gate structures are removed through a planarization process.

FIG. 12 shows a schematic flowchart of a step of replacing a portion of a first dielectric layer away from a semiconductor substrate with a second dielectric layer according to exemplary embodiments of the present application.

FIG. 13 shows a schematic flowchart of a step of forming a patterned third dielectric layer on a gate structure and a second dielectric layer according to exemplary embodiments of the present application.

FIG. 14 shows a schematic flowchart of a step of forming a third dielectric layer on a gate structure and a second dielectric layer that are not covered by a sacrificial mask layer according to exemplary embodiments of the present application.

FIG. 15 shows a schematic flowchart of a step of using a third dielectric layer as a mask to selectively remove a gate structure exposed by an opening to form a gate cutting groove according to exemplary embodiments of the present application.

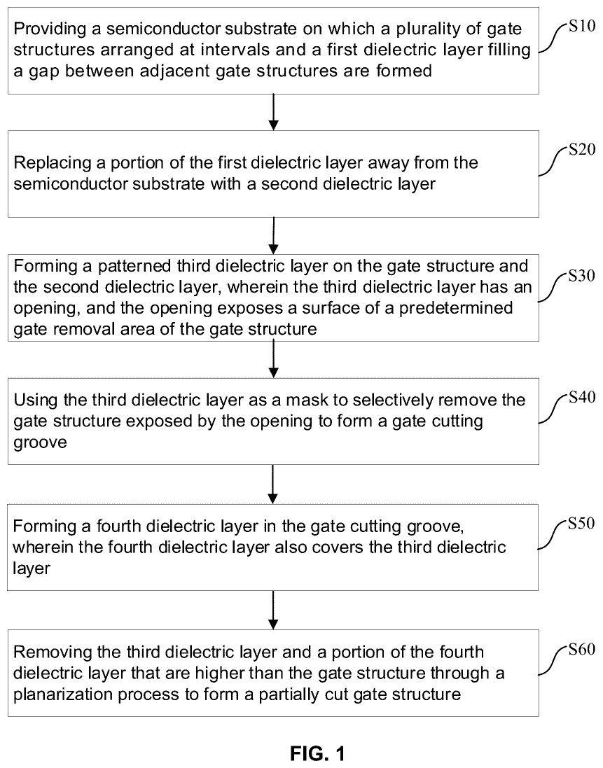

Component label description

| | |
|---|---|
| 100 | semiconductor substrate |
| 101 | bottom silicon layer |
| 102 | buried oxide layer |
| 103 | top silicon layer |
| 110 | trench |
| 120 | gate dielectric layer |
| 130 | first dielectric layer |
| 140 | gate structure |
| 141 | gate sacrificial layer |
| 142 | gate mask layer |
| 150 | sidewall structure |
| 150′ | sidewall support structure |
| 161 | second dielectric layer |
| 162 | third dielectric layer |
| 163 | fourth dielectric layer |
| 170 | sacrificial mask layer |
| 181 | opening |
| 182 | gate cutting groove |
| 190 | source/drain area |
| A1 | predetermined gate removal area |
| S10~S60 | steps |

### DESCRIPTION OF EMBODIMENTS

The following describes the implementation of the present application through specific examples. Those skilled in the art can easily understand other advantages and effects of the present application from the content disclosed in this specification. This application can also be implemented or applied through other different exemplary embodiments. Various details in this specification can also be modified or changed in various ways based on different viewpoints and applications without departing from the spirit of this application. When describing the embodiments of the present application in detail, for convenience of explanation, the cross-sectional views showing the device structure may not be drawn to scale and may be partially enlarged. In addition, the schematic views are only examples, which shall not limit the scope of protection of the present application. In addition, the three-dimensional dimensions with length, width, and depth should be included in actual production.

For the convenience of description, spatial relationship terms such as “below”, “under”, “beneath”, “lower than”, “above”, “on”, etc. may be used herein to describe the relationship of a component or feature to other components or features shown in the drawings. It will be understood that these spatial relationship terms are intended to encompass other orientations or directions of the device in use or operation in addition to the orientations or directions depicted in the figures. In addition, when a layer is referred to as being “between” two layers, it can be the only layer between the two layers or one or more intervening layers may also be present. In the context of this application, structures described as having a first feature “on” a second feature may include embodiments in which the first and second features are formed in direct contact and may include embodiments in which an additional feature is formed between the first and second features such that the first and second features may not be in direct contact.

It should be noted that the illustrations provided in these embodiments only illustrate the basic concept of the present application in a schematic manner, so the illustrations only show the components related to the present application and are not drawn based on the quantity, shape, and size of the components during actual implementation. In actual implementation, the shape, quantity, and scale of each component can be changed at will, and the component layout may also be more complex.

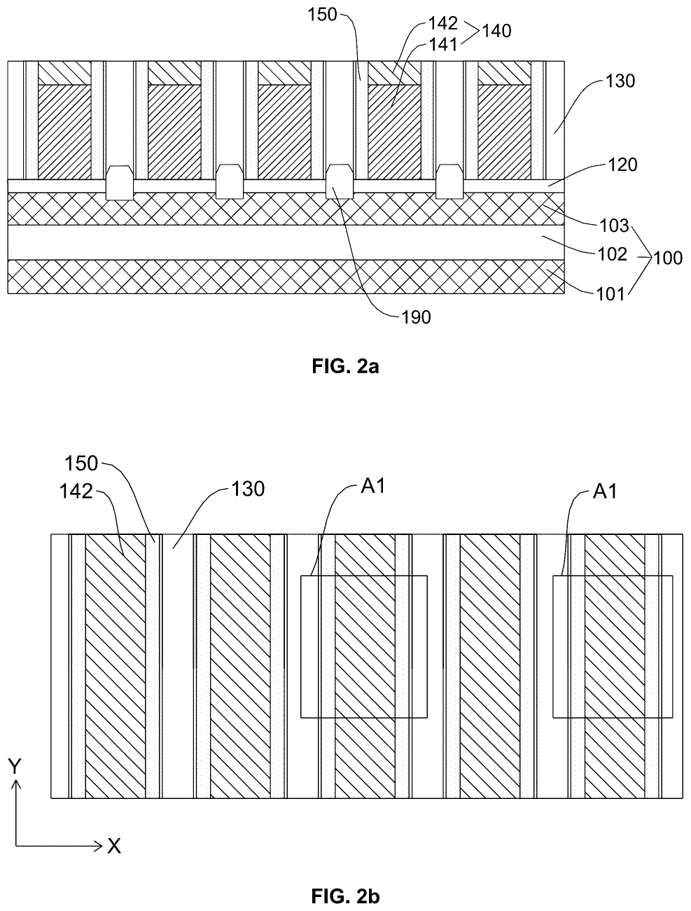

Exemplary embodiments of the present application provide a method for manufacturing a Metal-Oxide-Semiconductor (MOS) device, such as NMOS, PMOS, CMOS, etc. FIG. 2 shows a schematic flow chart of a method for manufacturing a semiconductor device according to exemplary embodiments.

As shown in FIG. 2, a method for manufacturing a semiconductor device includes the following steps.

S10: providing a semiconductor substrate, on which a plurality of gate structures arranged at intervals and a first dielectric layer filling a gap between adjacent gate structures are formed.

S20: replacing a portion of the first dielectric layer away from the semiconductor substrate with a second dielectric layer, wherein the hardness of the second dielectric layer is greater than the hardness of the first dielectric layer.

S30: forming a patterned third dielectric layer on the gate structures and the second dielectric layer, wherein the third dielectric layer has an opening, and the opening exposes the surface of a predetermined gate removal area of the gate structure.

S40: using the third dielectric layer as a mask to selectively remove the gate structure exposed by the opening to form a gate cutting groove.

S50: forming a fourth dielectric layer in the gate cutting grooves, wherein the fourth dielectric layer also covers the third dielectric layer.

S60: removing the third dielectric layer and a portion of the fourth dielectric layer that are higher than the gate structures through a planarization process to form a partially cut gate structure.

A method for manufacturing a semiconductor device of exemplary embodiments will be described in detail below with reference to the accompanying drawings corresponding to each step.

It should be noted that, for ease of explanation, a first direction X and a second direction Y may be defined as shown in FIG. 2b, where the first direction X is a direction along which the gate structures 140 are arranged, and the second direction Y is a direction along which the gate structures 140 extend. In exemplary embodiments, the first direction X is perpendicular to the second direction Y. In exemplary embodiments, the first direction and the second direction form a non-90° angle.

Referring to FIG. 2a and FIG. 2b. Step S10 is performed to provide a semiconductor substrate 100. The semiconductor substrate 100 may be any suitable substrate material, such as silicon, silicon on insulator (SOI), germanium, silicon carbide, silicon germanium, etc., or may be substrate materials in which a semiconductor epitaxial layer such as silicon carbide is epitaxially grown on the substrate. In exemplary embodiments, the semiconductor substrate 100 is an SOI substrate, which includes a bottom silicon layer 101, a buried oxide layer 102, and a top silicon layer 103 that are stacked in sequence.

Referring to FIG. 2a and FIG. 2b. A plurality of gate structures 140 and a first dielectric layer 130 filling the gap between adjacent gate structures 140 are formed on the semiconductor substrate 100 through processes such as deposition and etching. The plurality of the gate structures 140 is formed on the semiconductor substrate 100 at intervals along the first direction X. The gate structure 140 is a continuous linear gate structure 140 extending along the first direction X. The gate structure 140 may refer to either a final gate structure in a gate-fist process or a sacrificial gate structure in a gate-last process. FIG. 2b exemplarily shows two predetermined gate removal areas A1 (indicated by a rectangular dotted box in the figure). The portion of the gate structure 140 located in the predetermined gate removal area A1 needs to be cut out in subsequent steps. Each predetermined gate removal area A1 shown in FIG. 2b only spans one gate structure 140. It can be understood that, during actual application, in exemplary embodiments, the number of predetermined gate removal areas A1 is more than two. In exemplary embodiments, each predetermined gate removal area span two or more gate structures 140.

In exemplary embodiments, the gate structure 140 is a sacrificial gate structure, which includes a gate sacrificial layer 141 and a gate mask layer 142 formed on the gate sacrificial layer 141. For example, the gate sacrificial layer 141 is polycrystalline silicon. In exemplary embodiments, the gate mask layer 142 is made of silicon nitride, silicon oxycarbide, silicon oxynitride, aluminum oxynitride, or other materials, such as silicon nitride. In exemplary embodiments, the first dielectric layer 130 is a flowable medium layer with loose microstructure. The material of the flowable dielectric layer is flowable oxide (FOX). FOX refers to the flowable oxide material, which has high filling ability and uniformity and may be used to fill the gap between gates that has a high depth-to-width ratio.

Please continue to refer to FIG. 2a and FIG. 2b. A gate dielectric layer 120 is also formed between the semiconductor substrate 100 and the gate structure 140 for isolating the gate structure 140 and the semiconductor substrate 100. In exemplary embodiments, the gate dielectric layer 120 is silicon oxide. In exemplary embodiments, the gate dielectric layer 120 is formed through a thermal oxidation process. In exemplary embodiments, the gate dielectric layer 120 is formed through a deposition process. It can be understood that in exemplary embodiments, the gate dielectric layer 120 is silicon nitride or a high-k material with a higher dielectric constant than silicon oxide. For example, the high-k material includes, but not limited to at least one of: hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and any combination thereof.

Please continue to refer to FIG. 2a and FIG. 2b. A sidewall structure 150 is also formed between the sidewall of the gate structure 140 and the first dielectric layer 130. In exemplary embodiments, the sidewall structure 150 is formed by a deposition or planarization process. In exemplary embodiments, the sidewall structure 150 is made of one or more materials such as silicon oxynitride, carbon silicon oxynitride, silicon oxide, silicon oxycarbide, etc. The material of the sidewall structure 150 needs to have a higher etch selectivity ratio with respect to the material of the gate mask layer 142. For example, the planarization process is a chemical mechanical polishing (CMP for short) process.

Please continue to refer to FIG. 2a and FIG. 2b. A raised source/drain area is also formed on the semiconductor substrate 100. The source/drain area is located between the two adjacent gate structures 140 and is spaced apart from the corresponding gate structure 140 by the sidewall structures 150. The top of the source/drain area is higher than the bottom of the gate structure 140. The top of the source/drain area passes through the gate dielectric layer 120 from between the gate structures 140 and then extends into a top silicon layer 103 of the semiconductor substrate 100. In exemplary embodiments, the source/drain area is a non-protruding structure formed in the top silicon layer 103 of the semiconductor substrate 100.

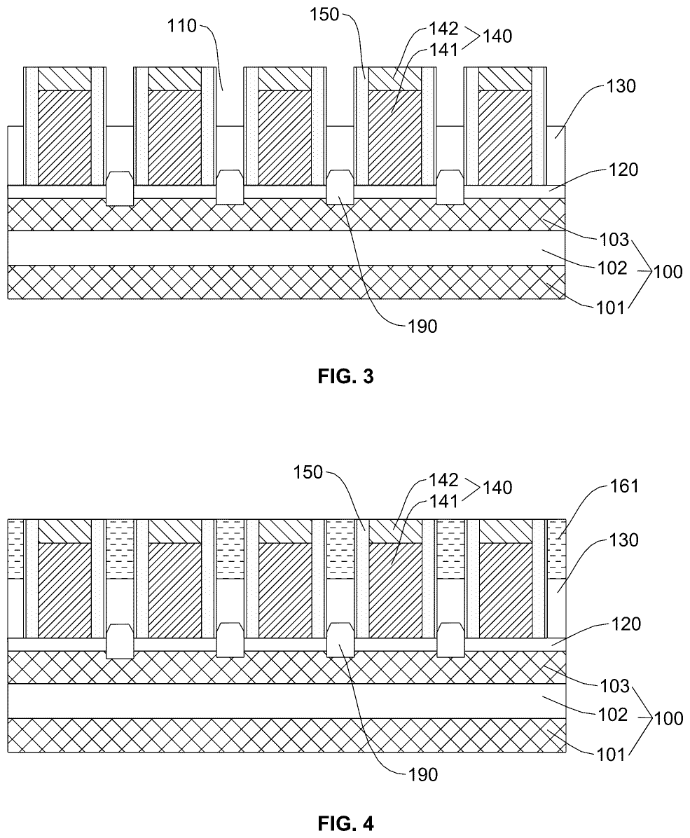

Please continue to refer to FIG. 3 and FIG. 4. Step S20 is performed to replace a portion of the first dielectric layer 130 away from the semiconductor substrate 100 with the second dielectric layer 161.

In exemplary embodiments, when using the second dielectric layer 161 to replace the portion of the first dielectric layer 130 away from the semiconductor substrate 100, as shown in FIG. 3, a dry or wet etching process is first used to etch the first dielectric layer 130 to remove the portion of the first dielectric layer 130 away from the semiconductor substrate 100 to form a trench 110 between the gate structures 140. In exemplary embodiments, the first dielectric layer 130 is a FOX layer with a loose microstructure. In exemplary embodiments, the FOX layer is etched downward through a SiCoNi process to form the trench 110. The width of the trench 110 is defined by the sidewall structures 150 on both sides. The depth of the trench 110 is greater than the thickness of the gate mask layer 142 of the gate structure 140.

Next, a second dielectric material layer (not shown) is formed in the trench 110. The second dielectric material layer fills the trench 110 and extends toward both sides to cover the upper surfaces of the gate structure 140 and the sidewall structure 150 on both sides of the trench 110.

Finally, as shown in FIG. 4, a portion of the second dielectric material layer higher than the gate structure 140 is removed through a planarization process such as CMP to form the second dielectric layer 161. The height from the bottom surface of the second dielectric layer 161 to the surface of the semiconductor substrate 100 is less than the height of the gate sacrificial layer 141.

In exemplary embodiments, the second dielectric layer 161 is a high-density plasma (HDP for short) dielectric layer. In exemplary embodiments, the trench 110 is filled with the second dielectric material layer through an HDP deposition process, and CMP is performed with the gate mask layer 142 as a stop layer, so that the second dielectric material layer is flush with the upper surface of the gate mask layer 142. The second dielectric material layer remained after CMP is used as the second dielectric layer 161. For example, the second dielectric layer 161 is made of silicon oxide.

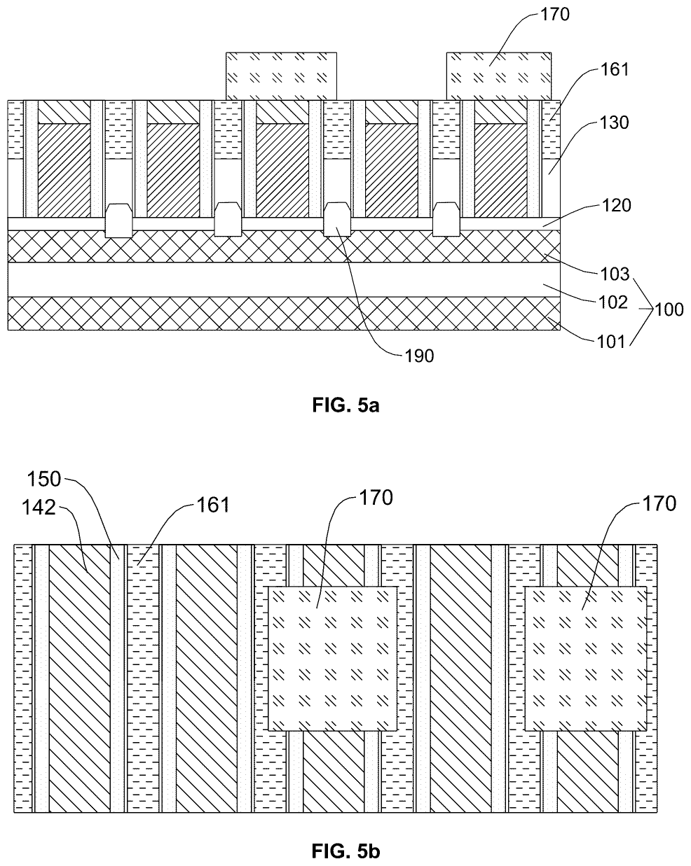

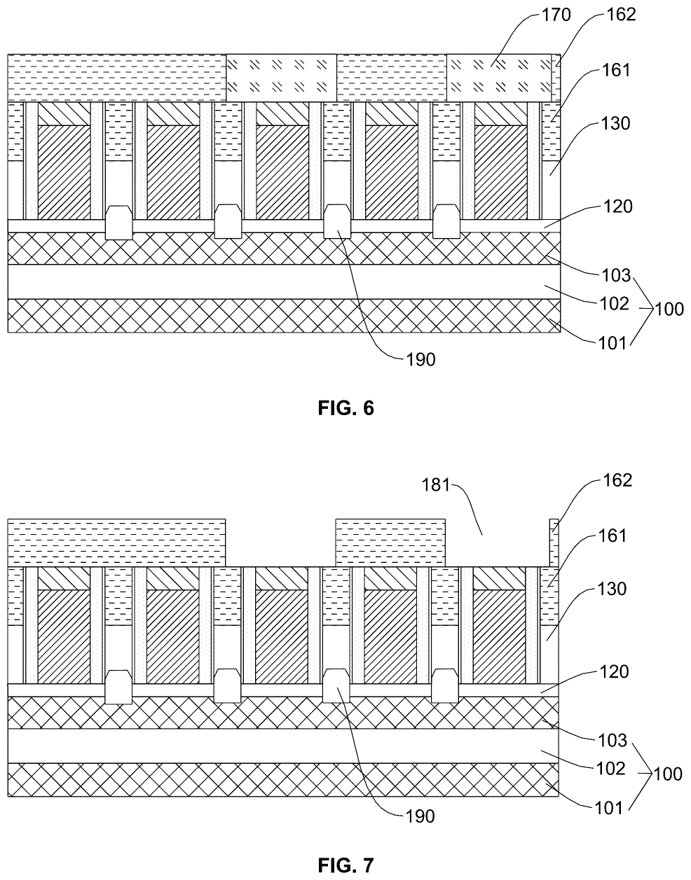

Please continue to refer to FIG. 5a, FIG. 5b, FIG. 6 and FIG. 7. Step S30 is performed to form a patterned third dielectric layer 162 on the gate structure 140 and the second dielectric layer 161. The third dielectric layer 162 has an opening 181, and the opening 181 exposes the surface of the predetermined gate removal area of the gate structure 140.

The step of forming the third dielectric layer 162 on the gate structure 140 and on the second dielectric layer 161 will be described hereinafter.

As shown in FIG. 5a and FIG. 5b, a patterned sacrificial mask layer 170 is first formed on the gate structure 140 and the second dielectric layer 161 through deposition and photolithography processes. The sacrificial mask layer 170 covers the surface of the predetermined gate removal area of the gate structure 140, the surface of the sidewall structures 150 on both sides of the gate structure 140, and the surface of a portion of the second dielectric layer 161. In exemplary embodiments, sacrificial polycrystalline silicon is first formed on the gate structure 140 and the second dielectric layer 161 through a deposition process, then a patterned photoresist layer (not shown) is formed on the sacrificial polycrystalline silicon, then the sacrificial polycrystalline silicon is etched using the patterned photoresist layer as a mask to form a sacrificial mask layer 170, and then the patterned photoresist layer is removed. Since the patterned photoresist layer is not in contact with the gate mask layer 142 of the gate structure 140, a loss of height of the gate structure 140 due to partial removal of the gate mask layer 142 caused when the patterned photoresist layer is removed may be avoided.

Next, as shown in FIG. 6, the third dielectric layer 162 is formed on the gate structure 140 and a portion of the second dielectric layer 161 that are not covered by the sacrificial mask layer 170 through deposition and planarization processes. The upper surface of the third dielectric layer 162 is flush with the upper surface of the sacrificial mask layer 170. In exemplary embodiments, the third dielectric layer 162 is an HDP dielectric layer. First, the third dielectric material layer is formed through an HDP deposition process, so that the third dielectric material layer covers the sacrificial mask layer 170 and the surfaces of the gate structure 140 and the portion of the second dielectric layer 161 that are exposed by the sacrificial mask layer 170. Then, a CMP process is performed with the sacrificial mask layer 170 as a stop layer, so that the upper surface of the third dielectric layer 162 is flush with the upper surface of the sacrificial mask layer 170. For example, the material of the third dielectric layer is silicon oxide.

Finally, as shown in FIG. 7, in exemplary embodiments, the sacrificial mask layer 170 is selectively removed through a wet etching or dry etching process to form the opening 181 in the third dielectric layer 162. The opening 181 corresponds to the predetermined gate removal area A1 in FIG. 2b. The width of the opening 181 (defined as the size of the opening 181 along the first direction X) is larger than the sum of the widths of the gate structure 140 and the sidewall structures 150 on both sides of the gate structure 140 so that the opening 181 completely exposes the surface of the predetermined gate removal area of the gate structure 140 and the surface of the sidewall structures 150 on both sides of the gate structure 140.

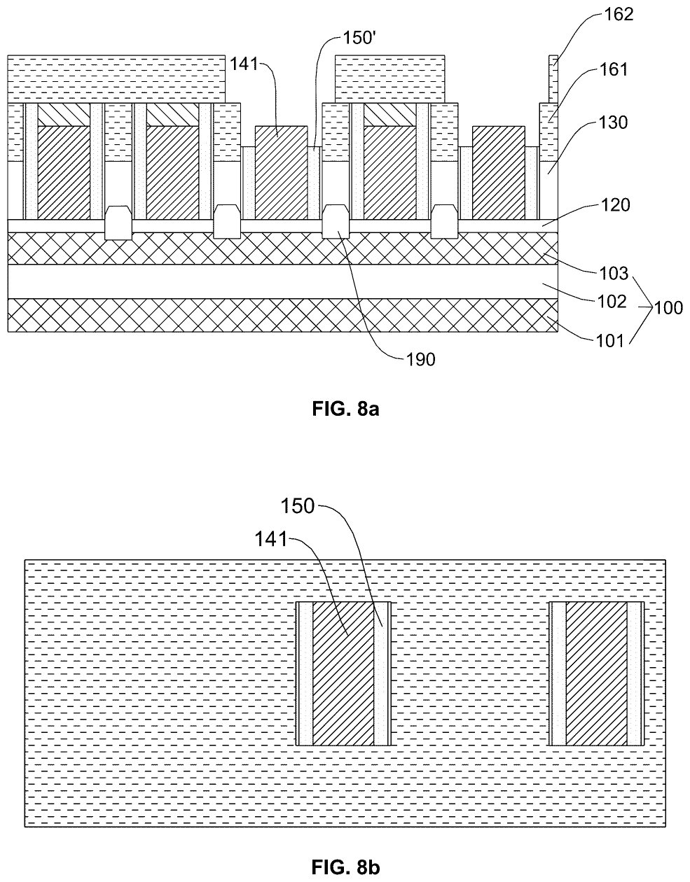

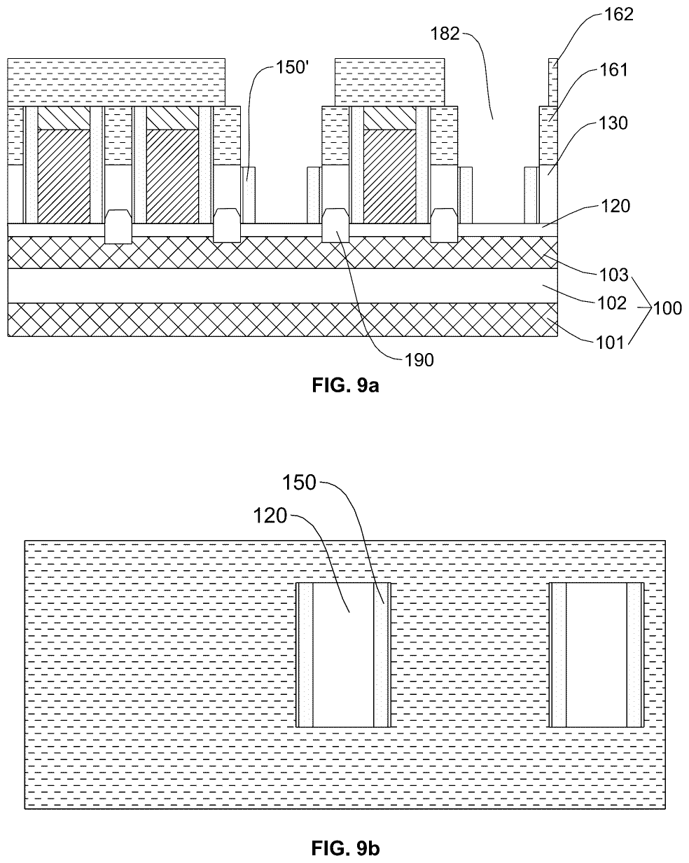

Referring to FIGS. 8a, 8b, 9a and 9b. Step S40 is performed to use the third dielectric layer 162 as a mask to selectively remove the gate structure 140 exposed by the opening 181 to form a gate cutting groove 182.

Using the third dielectric layer 162 as a mask to selectively remove the gate structure 140 exposed by the opening 181 to form the gate cutting groove 182 will be described hereinafter.

As shown in FIGS. 8a and 8b, in exemplary embodiments, first, the gate mask layer 142 exposed by the opening 181 is selectively removed through an etching process using the third dielectric layer 162 as a mask to expose the gate sacrificial layer 141.

Next, as shown in FIGS. 8a and 8b, in exemplary embodiments, a portion of the sidewall structure 150 exposed by the opening 181 is selectively removed through an etching process using the third dielectric layer 162 as a mask to form a sidewall support structure 150′. The sidewall support structure 150′ is used to support the first dielectric layer 130 with a loose microstructure on one side and may prevent the first dielectric layer 130 with a loose microstructure from deforming or collapsing after the gate sacrificial layer 141 is removed, thereby preventing the reliability of the semiconductor device from being affected. In exemplary embodiments, the height of the sidewall support structure 150′ is greater than or equal to the height of the first dielectric layer 130, that is, the top surface of the sidewall support structure 150′ is higher than the bottom surface of the second dielectric layer 161 or flush with the bottom surface of the second dielectric layer 161.

Finally, as shown in FIGS. 9a and 9b, in exemplary embodiments, the gate sacrificial layer 141 exposed by the opening 181 is selectively removed through an etching process using the third dielectric layer 162 as a mask, and the etching stops at the gate dielectric layer 120, thereby forming the gate cutting groove 182 in the semiconductor device. The gate cutting groove 182 divides the corresponding gate structure 140 into independent separated gate structures along its extension direction.

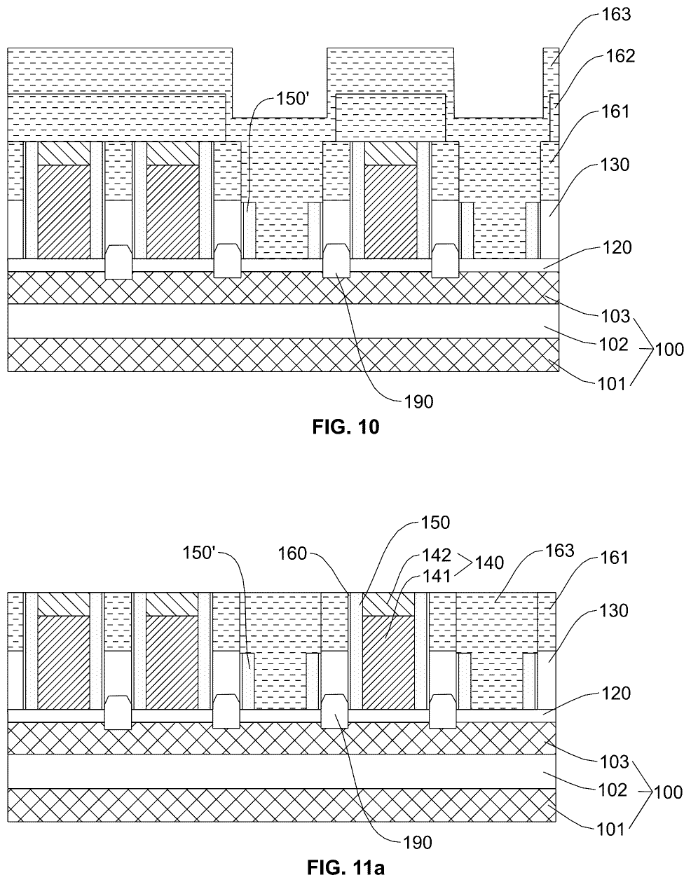

Please refer to FIG. 10. Step S50 is performed to form a fourth dielectric layer 163 in the gate cutting groove 182, and the fourth dielectric layer 163 also covers the third dielectric layer 162. In exemplary embodiments, the fourth dielectric layer 163 is an HDP dielectric layer, and the fourth dielectric layer 163 is formed in the gate cutting groove 182 and on the surface of the third dielectric layer 162 through an HDP deposition process. For example, the fourth dielectric layer 163 is made of silicon oxide.

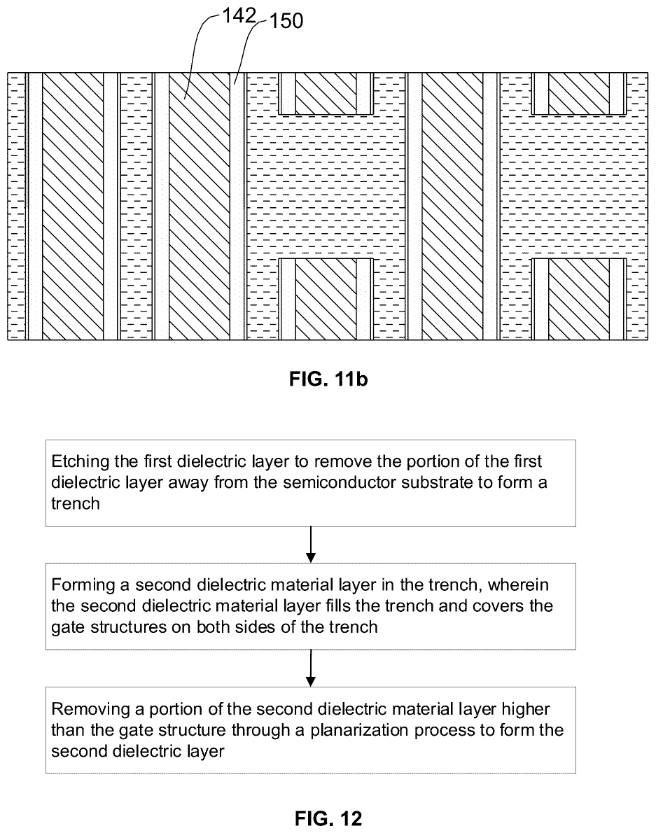

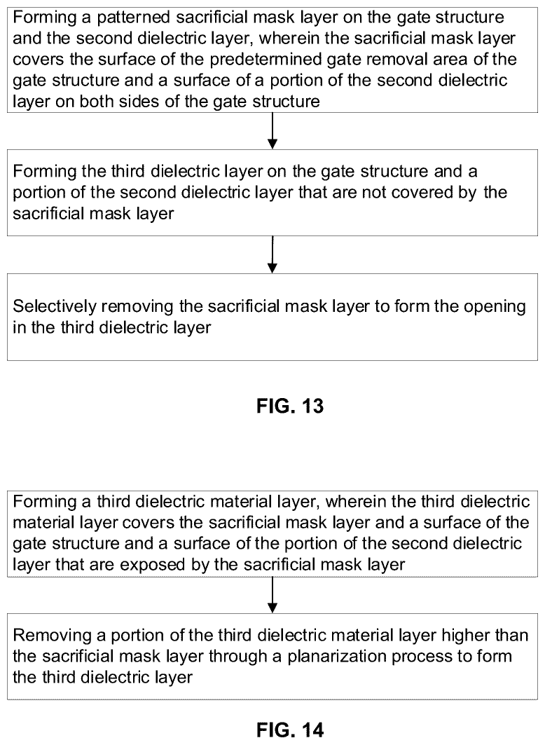

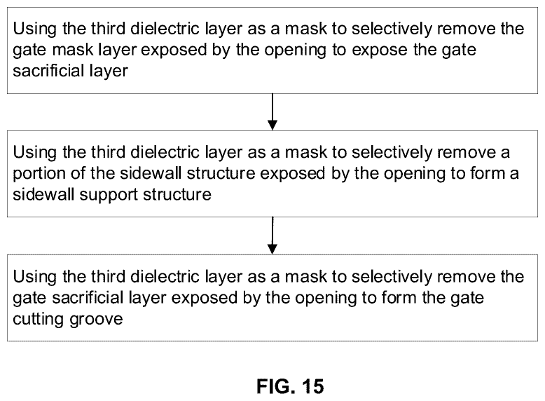

FIG. 11a and FIG. 11b. Step S60 is performed to remove the third dielectric layer 162 and a portion of the fourth dielectric layer 163 that are higher than the gate structure 140 through a planarization process to form a partially cut gate structure. In exemplary embodiments, a CMP process is performed using the gate mask layer 142 of the gate structure 140 as a stop layer to remove the third dielectric layer 162 and a portion of the fourth dielectric layer 163 that are higher than the gate structure 140. Four dielectric layers 163 are formed, so that the upper surface of the remaining fourth dielectric layer 163 is flush with the upper surface of the gate mask layer 142.

It should be noted that, in exemplary embodiments, the second dielectric layer 161, the third dielectric layer 162, and the fourth dielectric layer 163 are all formed using an HDP deposition process and are made of the same material. It can be understood that, in exemplary embodiments, the second dielectric layer 161, the third dielectric layer 162, and the fourth dielectric layer 163 are formed using different deposition processes, and their materials may not be exactly the same.

Based on the same inventive concept, the present application also provides a semiconductor device, which is formed using the above-mentioned manufacturing method. FIG. 11a and FIG. 11b show the schematic structural diagrams of the semiconductor device.

Please refer to FIG. 11a and FIG. 11b. The semiconductor device includes a semiconductor substrate 100, a plurality of gate structures 140, and an interlayer dielectric layer. In exemplary embodiments, a plurality of the gate structures 140 is arranged at intervals on the semiconductor substrate 100, a gate cutting groove 182 is formed in the gate structure 140 and passes through the gate structure 140 in a height direction, and the gate cutting groove 182 divides the corresponding gate structure 140 into independent separated gate structures along its extension direction. The interlayer dielectric layer is formed on the semiconductor substrate 100. The interlayer dielectric layer includes a first interlayer dielectric layer and a second interlayer dielectric layer that are arranged in a stacked way. The first interlayer dielectric layer refers to the first dielectric layer 130 shown in FIG. 11a, which fills the bottom of the gap between the gate structures 140. The second interlayer dielectric layer is the second dielectric layer 161 and the fourth dielectric layer 163 shown in FIG. 11a, which fills the top of the gap between the gate structures 140. The second interlayer dielectric layer also fills in the gate cutting groove 182.

In some embodiments of the present application, a sidewall support structure 150′ is provided between the first interlayer dielectric layer and the portion of the second interlayer dielectric layer filling in the gate cutting groove 182.

To sum up, the present application provides a semiconductor substrate 100, on which a plurality of gate structures 140 arranged at intervals and a first dielectric layer 130 filling between the gate structures are formed. A portion of the first dielectric layer 130 away from the semiconductor substrate 100 is replaced with a second dielectric layer 161. A patterned third dielectric layer 162 is formed on the gate structure 140 and the second dielectric layer 161. The third dielectric layer 162 has an opening 181. The opening 181 exposes the surface of a predetermined gate removal area of the gate structure 140. The third dielectric layer 162 is used as a mask to selectively remove the gate structure 140 exposed by the opening 181 to form a gate cutting groove 182. A fourth dielectric layer 163 is formed in the gate cutting groove 182. The fourth dielectric layer 163 also covers the third dielectric layer 162. The third dielectric layer 162 and a portion of the fourth dielectric layer 163 that are higher than the gate structure 140 are removed through a planarization process to form a partially cut gate structure.

In the present application, when the gate structure 140 in the predetermined gate removal area is etched, a certain height of sidewall structures 150 on both sides of the gate structure 140 in the predetermined gate removal area is retained as sidewall support structures 150′, which may support the first dielectric layer 130 with a loose microstructure, prevent the first dielectric layer 130 with a loose microstructure from deforming or collapsing after the gate structure 140 is removed, and improve the reliability of the semiconductor device.

In some exemplary embodiments, the height loss of the gate structure may be improved. In some exemplary embodiments, the difficulty to perform chemical mechanical grinding after the gate cutting groove is filled with FOX may be improved. In some exemplary embodiments, the occurrence of scratches and deformation may be improved. In some exemplary embodiments, the difficulty to maintain the smoothness of the grinding surface may be improved. In some exemplary embodiments, the consequent adverse effect on the subsequent process steps may be improved. In some exemplary embodiments, the performance of the final semiconductor device may be improved.

Compared with the existing gate cutting process, a loss of height of the gate structure due to the partial removal of the gate mask layer of the gate structure caused when the photoresist layer is removed may be avoided, thereby improving the reliability of the semiconductor device.

In this application, when the gate etching is performed, the sidewall structures of a certain height are retained on both sides of the gate structure as the sidewall support structures. This may support the first dielectric layer with loose microstructure on one side and may prevent the first dielectric layer with a loose microstructure from deformation or collapsing after the gate structure is removed, thereby improving the reliability of the semiconductor device.

The above embodiments only illustrate the principles and effects of the present application but are not used to limit the present application. Anyone familiar with this technology can modify or change the above embodiments without departing from the spirit and scope of the present application. Therefore, all equivalent modifications or changes made by those with ordinary knowledge in the technical field without departing from the spirit and technical ideas disclosed in this application shall still be covered by the claims of this application.

What is claimed is:

1. A method for manufacturing a semiconductor device, comprising:
providing a semiconductor substrate, on which a plurality of gate structures arranged at intervals and a first dielectric layer filling a gap between adjacent gate structures are formed;
replacing a portion of the first dielectric layer away from the semiconductor substrate with a second dielectric layer;
forming a patterned third dielectric layer on the gate structure and the second dielectric layer, wherein the third dielectric layer has an opening, and the opening exposes a surface of a predetermined gate removal area of the gate structure;
using the third dielectric layer as a mask to selectively remove the gate structure exposed by the opening to form a gate cutting groove;
forming a fourth dielectric layer in the gate cutting groove, wherein the fourth dielectric layer also covers the third dielectric layer; and
removing the third dielectric layer and a portion of the fourth dielectric layer that are higher than the gate structure through a planarization process to form a partially cut gate structure.

2. The method of manufacturing a semiconductor device according to claim 1, wherein, replacing the portion of the first dielectric layer away from the semiconductor substrate with the second dielectric layer includes:
etching the first dielectric layer to remove the portion of the first dielectric layer away from the semiconductor substrate to form a trench;
forming a second dielectric material layer in the trench, wherein the second dielectric material layer fills the trench and covers the gate structures on both sides of the trench; and
removing a portion of the second dielectric material layer higher than the gate structure through a planarization process to form the second dielectric layer.

3. The method for manufacturing a semiconductor device according to claim 1, wherein, the first dielectric layer includes a flowable dielectric layer; and each of the second dielectric layer, the third dielectric layer, and the fourth dielectric layer includes a high-density plasma dielectric layer.

4. The method of manufacturing a semiconductor device according to claim 1, wherein, forming the patterned third dielectric layer on the gate structure and the second dielectric layer includes:
forming a patterned sacrificial mask layer on the gate structure and the second dielectric layer, wherein the sacrificial mask layer covers the surface of the predetermined gate removal area of the gate structure and a surface of a portion of the second dielectric layer on both sides of the gate structure;
forming the third dielectric layer on the gate structure and a portion of the second dielectric layer that are not covered by the sacrificial mask layer; and
selectively removing the sacrificial mask layer to form the opening in the third dielectric layer.

5. The method of manufacturing a semiconductor device according to claim 4, wherein, forming the third dielectric layer on the gate structure and the portion of the second dielectric layer that are not covered by the sacrificial mask layer includes:
forming a third dielectric material layer, wherein the third dielectric material layer covers the sacrificial mask layer and covers a surface of the gate structure and a surface of the portion of the second dielectric layer that are exposed by the sacrificial mask layer; and
removing a portion of the third dielectric material layer higher than the sacrificial mask layer through a planarization process to form the third dielectric layer.

6. The method for manufacturing a semiconductor device according to claim 1, wherein, a sidewall structure is further formed on a sidewall of the gate structure, the gate structure includes a gate sacrificial layer and a gate mask layer formed on the gate sacrificial layer, and the opening exposes the surface of the predetermined gate removal area of the gate structure and a surface of the sidewall structure on both sides of the gate structure.

7. The method of manufacturing a semiconductor device according to claim 6, wherein, using the third dielectric layer as the mask to selectively remove the gate structure exposed by the opening to form the gate cutting groove includes:
using the third dielectric layer as a mask to selectively remove the gate mask layer exposed by the opening to expose the gate sacrificial layer;
using the third dielectric layer as a mask to selectively remove a portion of the sidewall structure exposed by the opening to form a sidewall support structure; and
using the third dielectric layer as a mask to selectively remove the gate sacrificial layer exposed by the opening to form the gate cutting groove.

8. The method of manufacturing a semiconductor device according to claim 6, wherein, in a step of replacing the portion of the first dielectric layer away from the semiconductor substrate with the second dielectric layer, a bottom surface of the second dielectric layer is lower than a top surface of the gate sacrificial layer.

9. The method for manufacturing a semiconductor device according to claim 7, wherein, in a step of using the third dielectric layer as the mask to selectively remove the portion of the sidewall structure exposed by the opening to form a sidewall supporting structure, a top surface of the sidewall support structure is higher than or flush with a bottom surface of the second dielectric layer.

10. A semiconductor device, wherein, comprising:
a semiconductor substrate;
a plurality of gate structures arranged at intervals on the semiconductor substrate, wherein a gate cutting groove is formed in the gate structure and passes through the gate structure along a height direction, and the gate cutting groove divides a corresponding gate structure into independent separated gate structures along an extending direction of the gate structure; and
an interlayer dielectric layer formed on the semiconductor substrate, wherein the interlayer dielectric layer includes a first interlayer dielectric layer and a second interlayer dielectric layer that are arranged in a stacked way, the first interlayer dielectric layer fills a bottom of a gap between the gate structures, the second interlayer dielectric layer fills a top of the gap between the gate structures, and the second interlayer dielectric layer also fills the gate cutting groove.

11. The semiconductor device according to claim 10, wherein, a sidewall support structure is provided between the first interlayer dielectric layer and a portion of the second interlayer dielectric layer filling the gate cutting groove.
